(19) United States
(12) Patent Application Publication
(10) Pub. No.: US 2013/0192655 A1
(43) Pub. Date: Aug. 1, 2013

(54) THERMOELECTRIC DEVICE EMBEDDED IN A PRINTED CIRCUIT BOARD

(71) Applicant: TEXAS INSTRUMENTS INCORPORATED, Dallas, TX (US)

(72) Inventors: Henry L. Edwards, Garland, TX (US); Kenneth J. Maggio, Dallas, TX (US); Steven Kummerl, Carrollton, TX (US); Sreenivasan K. Koduri, Allen, TX (US)

(21) Appl. No.: 13/798,805

(22) Filed: Mar. 13, 2013

Related U.S. Application Data
(63) Continuation-in-part of application No. 12/790,688, filed on May 28, 2010.
Application No. 12/790,688 is a continuation-in-part of application No. 12/201,679, filed on Aug. 29, 2008.
(60) Provisional application No. 61/182,052, filed on May 28, 2009.
(60) Provisional application No. 61/182,055, filed on May 28, 2009.
(60) Provisional application No. 60/968,805, filed on Aug. 29, 2007.

(51) Int. Cl. H01L 35/28; H01L 29/02

(52) U.S. Cl. CPC H01L 35/28; H01L 29/02
USPC 136/204; 136/200; 136/205; 438/55

(57) ABSTRACT

A circuit board with an embedded thermoelectric device with hard thermal bonds. A method of embedding a thermoelectric device in a circuit board and forming hard thermal bonds.

This application is a continuation-in-part of application Ser. No. 12/790,688 filed May 28, 2010, which application Ser. No. 12/790,688 is a continuation-in-part of application Ser. No. 12/201,679 filed Aug. 29, 2008 and also claims priority from and the benefit of Provisional Application Nos. 61/182,052 filed May 28, 2009 and 61/182,055 filed May 28, 2009; which application Ser. No. 12/201,679 claims priority from and the benefit of Application No. 60/968,805 filed Aug. 29, 2007; the entireties of all of which are incorporated herein by reference.

### BACKGROUND

This relates to the field of integrated circuit packaging. More particularly, this relates to embedding a thermoelectric device in circuit boards.

Conventional thermoelectric devices are formed using a pair of ceramic plates with metal traces typically electroplated on the surface. The thermopiles may be macroscopic pellets of n-type and p-type doped thermoelectric material such as bismuth telluride or lead telluride soldered to the metal traces on the ceramic plates to form a sandwich structure. The thermopile array is typically connected electrically in series through the electroplated metal traces. The thermopile array is connected thermally in parallel with the heat flowing from one ceramic plate through the thermopiles to the other ceramic plate.

The thermoelectric device may be used to harvest heat from the surrounding ambient to generate electrical power using the Seebeck effect or electrical current may be run through the thermoelectric device to pump heat away using the Peltier effect.

It is desirable to embed thermoelectric devices in circuit boards to harvest heat generated by integrated circuit components or to cool the integrated circuit components.

One difficulty in embedding conventional thermoelectric devices is that the temperatures reached during conventional circuit board manufacturing processes may cause the solder joints in the conventional thermoelectric device to fail.

Another difficulty is that the pressures used during the lamination process during conventional circuit board manufacturing may damage the fragile ceramic plates and thermoelectric materials.

Yet another difficulty is forming good electrical and thermal contacts to a conventional thermoelectric device that is embedded in a circuit board. Because of the difference in the coefficients of thermal expansion of the thermo conductors from the heat source and heat sink versus the ceramic plates and the thermoelectric material, the bonding of thermoconductors directly to the conventional thermoelectric device may cause stresses to develop during temperature changes that may cause conventional thermoelectric devices to fail. For this reason conventional thermoelectric devices are typically attached to heat sources and sinks using thermal grease which has poor thermal conductivity. Consequently, manufacturers of conventional thermoelectric devices typically publish detailed instructions with elaborate procedures describing how to obtain acceptable thermal and mechanical mounting.

### SUMMARY

A thermoelectric device embedded in a circuit board with a hard thermal bond to a heat source or a heat sink. A method of embedding a thermoelectric device in a circuit board using conventional circuit board processing and forming hard thermal bonds to the embedded thermoelectric device.

### BRIEF DESCRIPTION OF THE DRAWINGS

FIG. 1 is a cross-sectional view of an embodiment of the principles of the invention.

FIGS. 2A-2H are illustrations of steps in the fabrication of a thermoelectric device embedded in a circuit board formed according to principles of the invention.

FIG. 3 is a plan view of an embodiment of the principles of the invention.

FIG. 4 is a cross-sectional view of an embodiment of the principles of the invention.

### DETAILED DESCRIPTION OF EXAMPLE EMBODIMENTS

Thermoelectric devices may be formed using the same manufacturing processes used to form integrated circuits as described in application Ser. No. 12/201,679 filed Aug. 29, 2008, incorporated herein by reference. An integrated thermoelectric device formed in this way may be a standalone device or may be embedded in an integrated circuit. Integrated thermoelectric devices formed using integrated circuit manufacturing processes are less fragile than conventional thermoelectric devices which may be formed by soldering thermopiles to ceramic plates. Unlike the conventional devices, integrated thermoelectric devices may be embedded in circuit boards using standard integrated circuit embedding techniques. In addition, metal heat conductors may be bonded directly to the integrated thermoelectric devices using a technique such as soldering which forms a much better thermal conductive interface than the thermal grease typically used with conventional devices.

The term “hard thermal bond” refers to forming a bond between two thermally conductive materials using a highly thermally conductive material and method. For example two metallic rods may be soldered or welded or attached together with thermally conductive epoxy to form a hard thermal bond.

The term “soft thermal bond” refers to forming a bond between two thermally conductive materials by applying pressure to hold the two thermally conductive materials in contact with each other. A thermally conductive grease may be applied to improve heat transfer through a soft thermal bond.

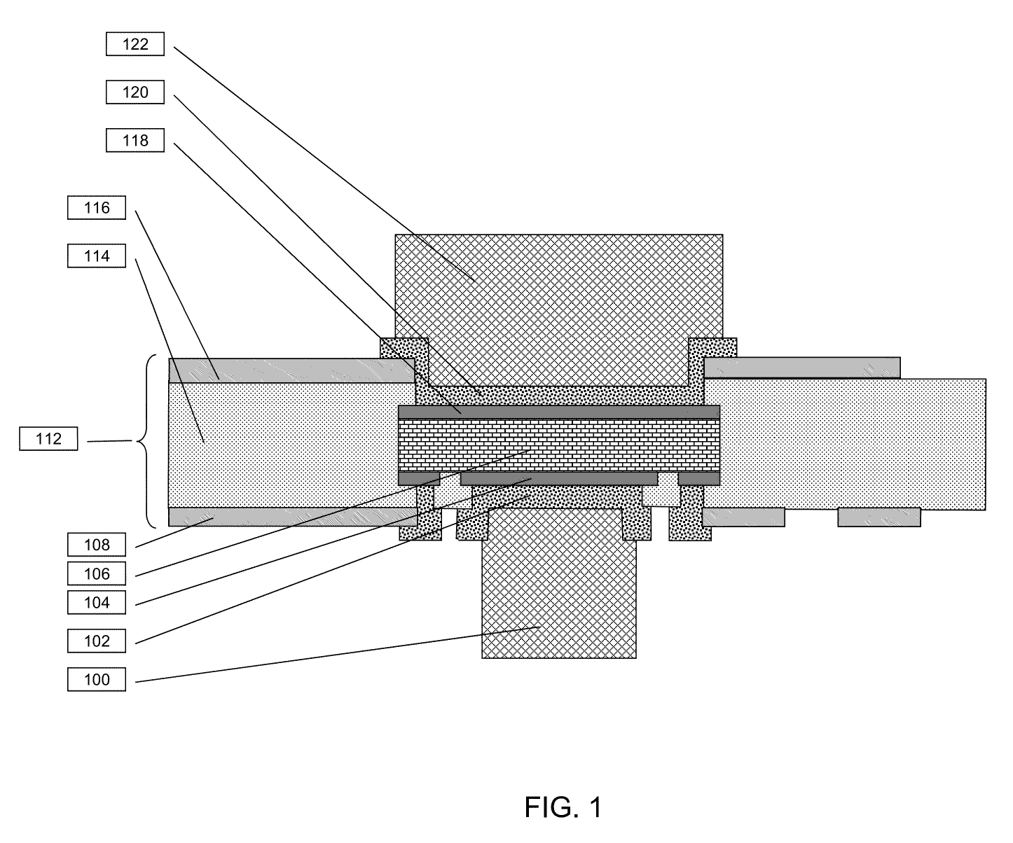

FIG. 1 shows an integrated thermoelectric device 106 embedded in a circuit board, 112. Thermal heat source and heat sink elements 100, 122 may be attached with hard thermal bonds to opposite sides of the device 106 to heat one side and cool the other. Circuit board 112 may be comprised of several layers including copper traces on the top and bottom surfaces 106, 108. The circuit board 112 may be filled with a structural insulator 114 such as an epoxy that may contain a reinforcement such as fiberglass. Front and back contacts 102, 120 to thermal bondpads 104, 118 on device 106 may be formed by electroplating. Unlike conventional devices which typically use grease, the device 106 may be directly coupled to the heat source and sink using a hard thermal bonding technique such as soldering. The hard thermal bonding significantly improves thermal conduction to and away from device 106. The heat source 100 may be a integrated circuit power device or microprocessor unit (MPU), for example. The heat sink 122 may for example be air cooled or liquid cooled fins, may be a fan, or may be a heat pipe. The integrated thermoelectric device 106 may be a standalone thermoelectric device such as a thermoelectric generator or a thermoelectric cooler or it may be embedded within an integrated circuit chip.

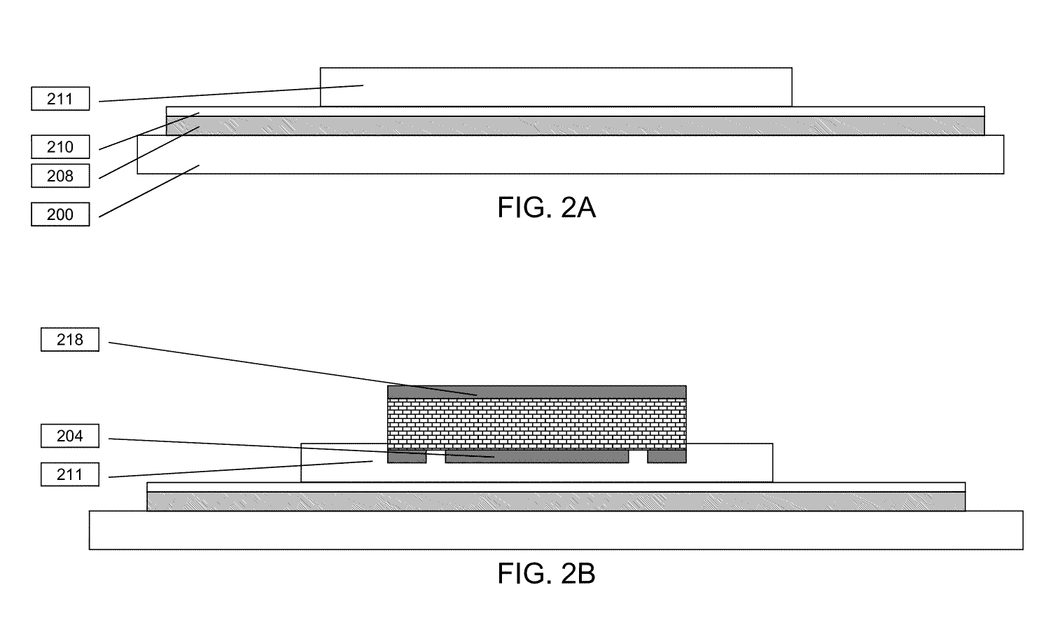

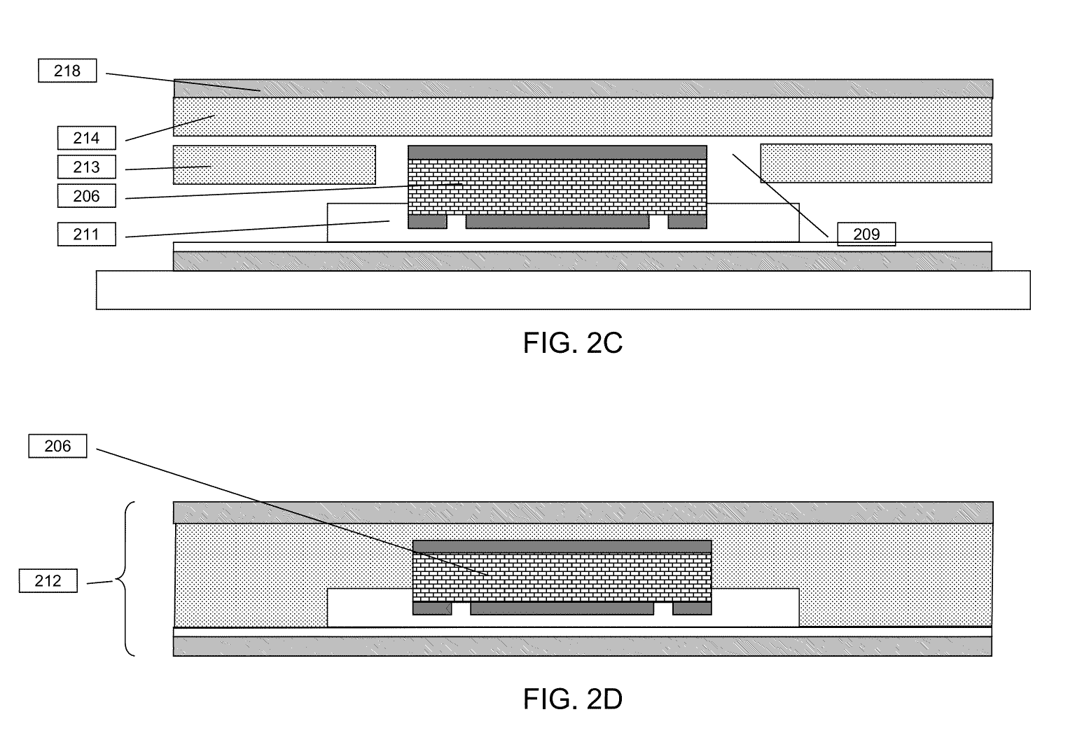

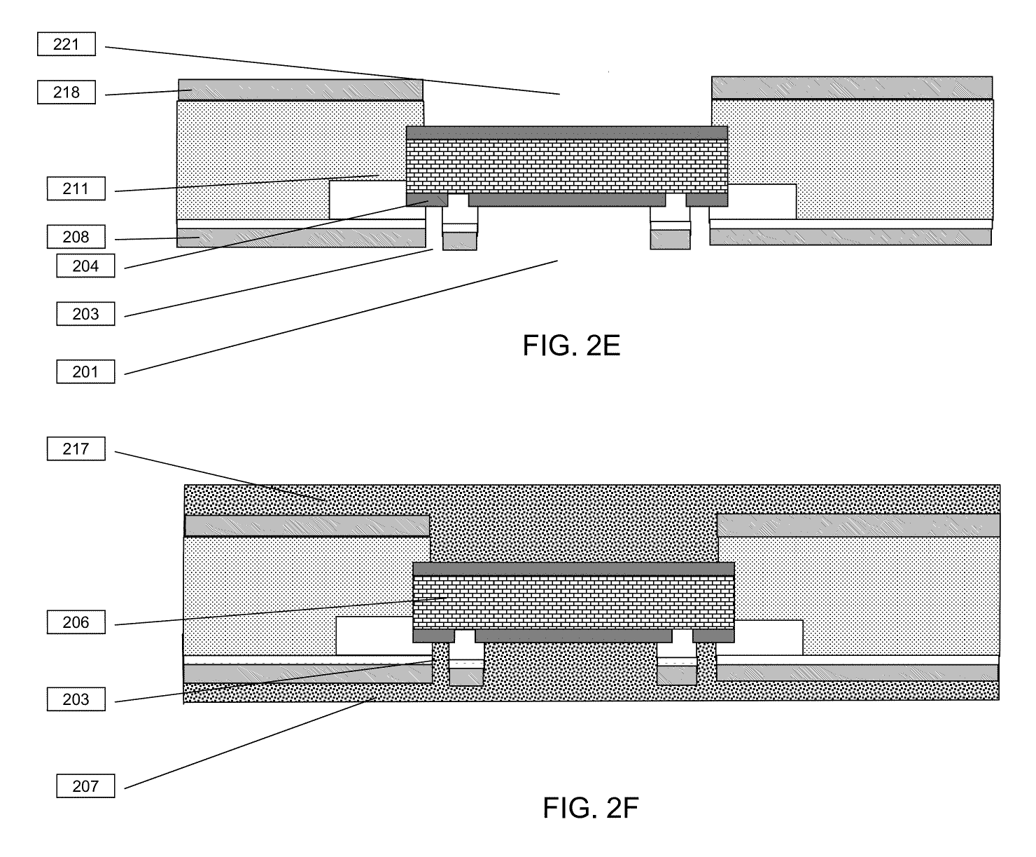

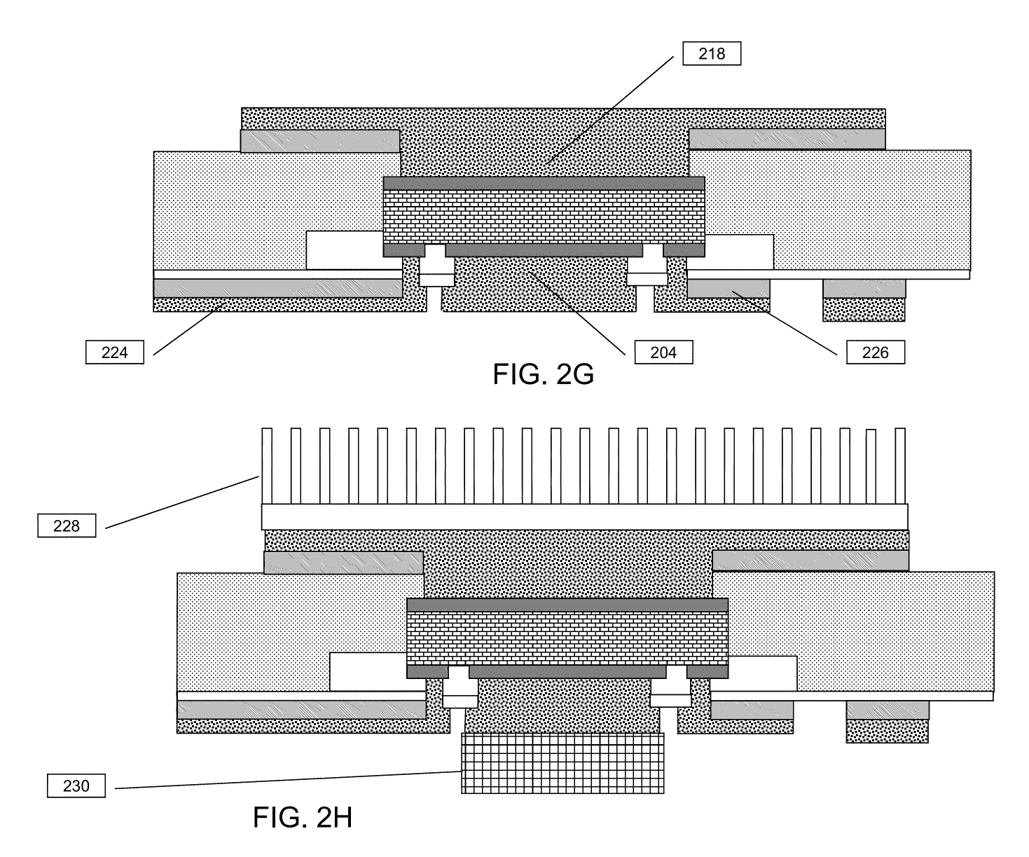

An example process flow for embedding an integrated thermoelectric device in a circuit board is described with reference to FIGS. 2A-2H. The process for illustrating the embedding process is similar to the Austria Technologie and Systemtechnik process flow, but other process flows for embedding integrated circuits may also be used.

FIG. 2A shows a circuit board support 200 with a layer of resin coated copper foil (RCC) 208 attached. The resin coating 210 may be reinforced with a material such as fiberglass to provide additional strength to the circuit board. This resin, 210 may be fully cured to preserve structural integrity during subsequent thermal cycles. Die attach epoxy 211 is placed on the RCC where the integrated thermoelectric device is to be placed. The die attach epoxy 211 may be partially cured. Instead of die attach epoxy, a silicone based tape may optionally be used for die attach.

In FIG. 2B, an integrated thermoelectric device 206 is placed on the die attach epoxy 211. The epoxy may then be cured at a temperature of approximately 175° C., to fully cure the epoxy to hold the device 218 in place and to prevent deformation during subsequent thermal cycles.

In FIG. 2C, a layer (or layers) of partially cured epoxy 213, 214 (called b-stage epoxy) may be layered on top. A portion of the b-stage epoxy layer 213 may be hollowed out at 209 to accommodate the device 206. The hollowed out area 209 is typically formed by laser ablation. A top layer consisting of a resin coated copper foil 218 may be added. The resin may also be a partially cured epoxy resin. It may also contain reinforcement such as fiberglass if desired.

The structure described in FIG. 2C may then be placed in a hot pressure lamination tool to first pull a vacuum and then to apply heat and pressure to form the integrated circuit board 212 with embedded integrated thermoelectric device 206, as shown in FIG. 2D. Vacuum followed by pressure helps facilitate the b-stage resin flow and removal of voids. In a preferred embodiment, a vacuum is first drawn and then heat of approximately 180° C. and pressure of approximately 400 psi is applied to the circuit board structure 212 for about 70 minutes, causing the b-stage epoxy to first melt and flow and then to fully cure. The circuit board support 200 may then be removed. Process conditions may change depending upon the particular resin being used and details of the circuit board being formed.

Openings such as vias 203 and openings 201, 221 for heat trace connections to a heat source and heat sink may be formed by laser drilling. If desired the copper 208, 218 may be patterned and removed from the areas to be laser drilled. Metal bonding pads 204 may be formed as a final step in the integrated circuit manufacturing process or may be formed during the packaging process prior to dicing the wafer. The bonding pads 204 must be sufficiently large to account for laser misalignment and also must be sufficient large to withstand heating from the laser without delaminating.

Metal layers 207, 217, shown in FIG. 2F, may then be formed on the circuit board by sputtering or by electroplating. In a preferred embodiment, a seed layer of Pd is deposited on both sides of the circuit board by electroless plating followed by electroless copper plating. The metal layers 207, 217 fill the vias 203 and thermal openings 203, 221 forming electrical and thermal connection to the device 206. The metal layers 208, 218 may completely fill the thermal vias 201, 221, as shown FIG. 2F, or may partially fill the thermal vias as shown in FIG. 1 with metal layers 102, 120.

The metal layers 208, 218 may then be patterned and etched as shown in FIG. 2G to form electrical traces 224, 226, as well as thermal traces 204, 218 on both sides of the circuit board.

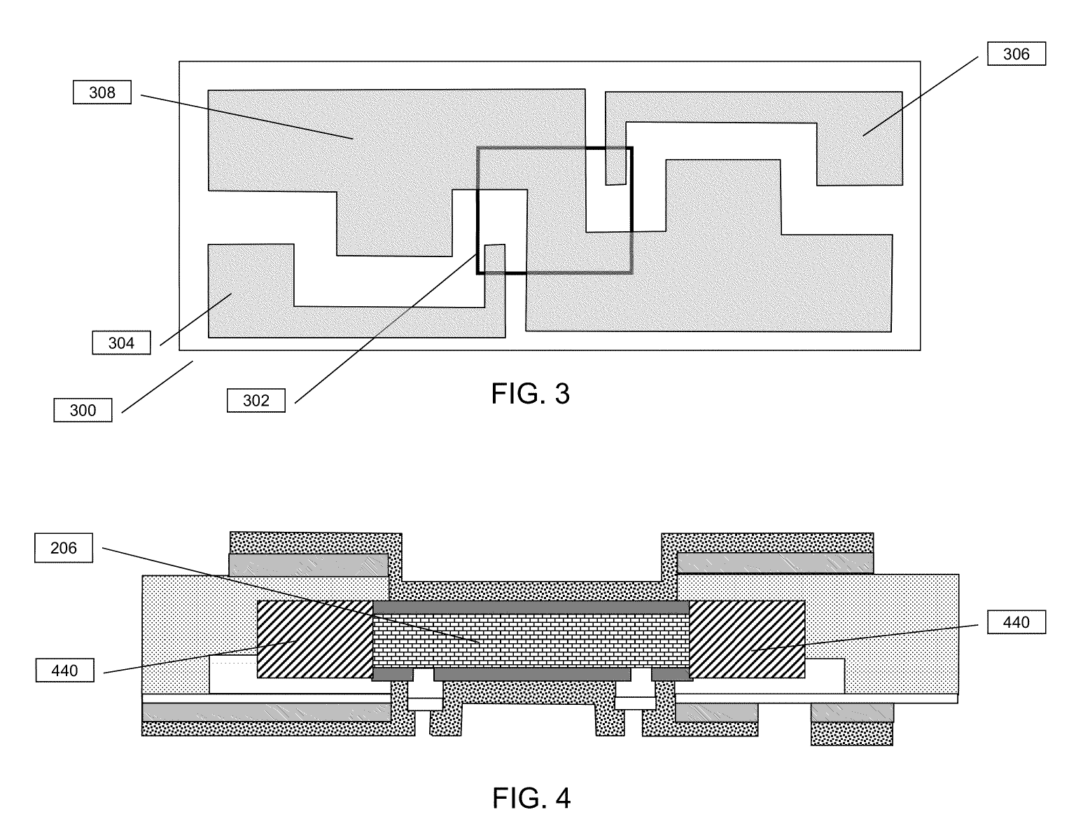

An example top view of a circuit board 300 showing the thermal trace 308 and the electrical traces 304, 306 is shown in FIG. 3. In this example, the electrical traces are separate from the thermal traces, but in some applications a trace may perform a dual function of conducting both thermal energy and electrical energy. As shown in this example, the thermal trace may be formed over a large portion of the circuit board to better collect or dissipate thermal energy.

As shown in FIG. 2H, a heat source 230 and a heat sink 228 may be bonded directly to the thermal traces using hard thermal bonding techniques such as soldering that have excellent thermal conductivity. Spring-loaded connections with thermally conductive grease such as is used for conventional devices may also be used, but this may significantly reduce the thermal conductivity. The heat source 230 may be a power amplifier, an MPU, or some other heat source. The heat sink 228 may be metal fins as shown in FIG. 2H or may be a fan or an air or liquid cooled cavity, for example.

A thermal insulating block may be placed around the integrated thermoelectric device when it is placed in the die attach epoxy 204, as in FIG. 2B, to reduce lateral heat flow from the device 206, and improve efficiency of the integrated thermoelectric device. Vertical heat flow through the integrated thermoelectric device may be used to harvest energy, whereas heat that flows laterally may be wasted.

Those skilled in the art to which this invention relates will appreciate that many other embodiments and variations are possible within the scope of the claimed invention.

What is claimed is:

1. A circuit board, comprising:
an integrated thermoelectric device embedded in the circuit board that has a hard thermal bond to a heat source or a heat sink.

2. The circuit board of claim 1, wherein the integrated thermoelectric device is a stand alone integrated thermoelectric device.

3. The circuit board of claim 1, wherein the integrated thermoelectric device is a thermoelectric device embedded in an integrated circuit chip.

4. The circuit board of claim 1, wherein the integrated thermoelectric device is a thermoelectric generator.

5. The circuit board of claim 1, wherein the integrated thermoelectric device is a thermoelectric cooler.

6. The circuit board of claim 1, further comprising a thermal insulating block surrounding the integrated thermoelectric device.

7. The circuit board of claim 1, wherein the heat source is an integrated circuit chip.

8. The circuit board of claim 1, further comprising electrical and thermal traces.

9. The circuit board of claim 8, wherein the traces comprise separate electrical and thermal traces.

10. The circuit board of claim 8, wherein the traces are dual function electrical and thermal traces.

11. A method of embedding an integrated thermoelectric device in a circuit board, comprising;
placing the integrated thermoelectric device onto die attach epoxy on a first resin coated copper film;
adding a layer of partially cured epoxy resin over the integrated thermoelectric device;
placing a second resin coated copper film over the layer of partially cured epoxy resin;
hot pressure laminating the first resin coated copper film, the integrated thermoelectric device, the layer of partially cured epoxy resin and the second resin coated copper film to form the circuit board with the integrated thermoelectric device embedded;
laser drilling openings in a front side and a back side of the circuit board to metal pads on the integrated thermoelectric device;
forming metal layers on the front side and the back side of the circuit board which at least partially fill the openings;
patterning and etching the metal layers on the front side and the back side of the circuit board to form electrical and thermal traces; and
forming a hard thermal bond between the thermal trace and a heat source or a heat sink.

12. The method of claim 11, wherein a hollowed out area is formed in the layer of partially cured epoxy resin to accommodate the integrated circuit device.

13. The method of claim 11, further comprising placing thermal insulating material around the integrated thermoelectric device and placing the thermal insulating material onto the die attach epoxy.

14. The method of claim 11, wherein the hard thermal bond is formed by soldering.

15. The method of claim 11, wherein the thermal traces and the electrical traces are separate.

16. The method of claim 11, wherein the thermal trace is also an electrical trace.

17. The method of claim 11, wherein the integrated thermoelectric device is a stand alone thermoelectric device.

18. The method of claim 11, wherein the integrated thermoelectric device is embedded in an integrated circuit.

19. The method of claim 11, wherein the integrated thermoelectric device is a thermoelectric generator.

20. The method of claim 11, wherein the integrated thermoelectric device is a thermoelectric cooler.
